(19) United States
(12) Patent Application Publication
(10) Pub. No.: US 2026/0082548 A1
(43) Pub. Date: Mar. 19, 2026

(54) SEMICONDUCTOR MEMORY DEVICE

(71) Applicant: Samsung Electronics Co., Ltd., Suwon-si (KR)

(72) Inventors: Seok-Won KIM, Suwon-si (KR); Jung Ha LEE, Suwon-si (KR); Do Sun LEE, Suwon-si (KR); Sun Jung LEE, Suwon-si (KR); Sang Hyun PARK, Suwon-si (KR)

(73) Assignee: Samsung Electronics Co., Ltd., Suwon-si (KR)

(21) Appl. No.: 19/233,463

(22) Filed: Jun. 10, 2025

(30) Foreign Application Priority Data
Sep. 13, 2024 (KR) 10-2024-0126147

(51) Int. Cl. H10B 12/00; G11C 5/06; H10D 1/68; H10D 62/80; H10D 62/83; H10D 64/66

(52) U.S. Cl. CPC H10B 12/482; G11C 5/063; H10B 12/488; H10D 1/714; H10D 62/83; H10D 62/875; H10D 62/883; H10D 64/668

(57) ABSTRACT

A semiconductor memory device semiconductor memory device includes a substrate, a plurality of wordlines stacked in a first direction on the substrate, channel regions between adjacent wordlines in the first direction and extending in a second direction, first source/drain regions on first sides of the channel regions, second source/drain regions on second sides of the channel regions, bitlines extending in the first direction on the substrate and connected to corresponding ones of the first source/drain regions, respectively, data storage elements connected to the second source/drain regions, respectively, and capping films between the second source/drain regions and corresponding ones of the data storage elements, respectively, the capping filing including insertion holes, respectively, wherein at least portions of the second source/drain regions are inserted into corresponding ones of the insertion holes of the capping films, respectively.

### CROSS-REFERENCE TO RELATED APPLICATION

This application claims priority from Korean Patent Application No. 10-2024-0126147 filed on Sep. 13, 2024 in the Korean Intellectual Property Office, and all the benefits accruing therefrom under 35 U.S.C. 119, the contents of which in its entirety are herein incorporated by reference.

### BACKGROUND

### 1. Field

The present disclosure relates to semiconductor memory devices.

### 2. Description of the Related Art

In the case of conventional two-dimensional (2D) or planar semiconductor devices, the integration density is primarily determined by the area occupied by a unit memory cell, and is thus significantly affected by the level of fine patterning technology. However, because ultra-expensive equipment is desired for fine patterning, the integration density of 2D semiconductor devices, though increasing, remains limited. Accordingly, three-dimensional (3D) semiconductor memory devices comprising memory cells arranged three-dimensionally have been proposed.

### SUMMARY

Some example embodiments of the present disclosure provide semiconductor memory devices with improved performance and reliability.

Some example embodiments of the present disclosure also provide a tiled display device capable of

However, example embodiments of the present disclosure are not restricted to those set forth herein. The above and other aspects of the present disclosure will become more apparent to one of ordinary skill in the art to which the present disclosure pertains by referencing the detailed description of some example embodiments given below.

According to an example embodiment of the present disclosure, a semiconductor memory device includes a substrate, a plurality of wordlines stacked in a first direction on the substrate, channel regions between corresponding pairs of adjacent wordlines from among the plurality of wordlines, respectively, in the first direction, the channel regions extending in a second direction, first source/drain regions on first sides of the channel regions, respectively, second source/drain regions on second sides of the channel regions, respectively, bitlines extending in the first direction on the substrate, each of the bitlines connected to a group of the first source/drain regions, data storage elements on the substrate and connected to corresponding ones of the second source/drain regions, respectively, and capping films between the second source/drain regions and corresponding ones of the data storage elements, respectively, the capping film including insertion holes, respectively, wherein first portions of the second source/drain regions are inserted into corresponding ones of the insertion holes of the capping films, respectively.

According to an example embodiment of the present disclosure, a semiconductor memory device includes a substrate, a plurality of wordlines stacked in a first direction on the substrate, semiconductor patterns between corresponding pairs of adjacent wordlines from among the plurality of wordlines in the first direction, the semiconductor patterns extending in a second direction, the semiconductor patterns including first terminals and second terminals, each of the first terminals and a corresponding one of the second terminals spaced apart in the second direction, bitlines extending in the first direction on the substrate, each of the bitlines connected to a group of the first terminals of the semiconductor patterns, capping films connected to corresponding ones of the second terminals of the semiconductor patterns, respectively, and data storage elements connected to corresponding ones of the capping films, respectively, wherein the capping films include vertical portions, protruding portions, and insertion holes, each of the insertion holes defined by a corresponding one of the vertical portions and a corresponding one of the protruding portions, the vertical portions in contact with corresponding ones of the data storage elements, respectively, the protruding portions extending from corresponding ones of the vertical portions, respectively, in the second direction, and first portions of the semiconductor patterns each are inserted into a corresponding one of the insertion holes at a corresponding one of the second terminals.

According to an example embodiment of the present disclosure, a semiconductor memory device includes a substrate, a plurality of wordlines stacked in a first direction on the substrate, channel regions between corresponding pairs of adjacent wordlines from among the plurality of wordlines, respectively, in the first direction, the channel regions extending in a second direction, first source/drain regions on first sides of the channel regions, respectively, second source/drain regions on second sides of the channel regions, respectively, bitlines extending in the first direction on the substrate, each of the bitlines connected to a group of the first source/drain regions, data storage elements on the substrate and connected to corresponding ones of the second source/drain regions, respectively, inner insulating films on corresponding ones of the second source/drain regions, respectively, and capping films between the second source/drain regions and corresponding ones of the data storage elements, respectively, the capping films including vertical portions in contact with corresponding ones of the data storage elements, respectively, and protruding portions extending from corresponding ones of the vertical portions, respectively, in the second direction, the protruding portions being in contact with corresponding ones of the inner insulating films, respectively, wherein the second source/drain regions include first portions covered by the capping films and second portions covered by the inner insulating films, the first portions include first surfaces, upper surfaces, lower surfaces, first side surfaces and second side surfaces, the first surfaces being in contact with corresponding ones of the vertical portions, respectively, each of the upper surfaces and a corresponding one of the lower surfaces being in contact with a corresponding one of the protruding portions, each of the lower upper surfaces and a corresponding one of the lower surfaces being opposite to each other in the first direction, each of the first side surfaces and a corresponding one of the second side surfaces being in contact with a corresponding one of the protruding portions, each of the first side surfaces and a corresponding one of the second side surfaces being opposite to each other in a third direction, the capping films are in contact with the first surfaces, the upper surfaces, the lower surfaces, the first side surfaces, and the second side surfaces of the first portions, and each of the upper surfaces of the inner insulating films and a corresponding one of upper surfaces of the capping films are on a same plane.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail some example embodiments thereof with reference to the attached drawings, in which:

FIG. 1 is an example circuit diagram illustrating a cell array of a semiconductor memory device according to some example embodiments of the present disclosure.

FIG. 2 is an example perspective view illustrating a semiconductor memory device according to some example embodiments of the present disclosure.

FIG. 3 is an example plan view illustrating a semiconductor memory device according to some example embodiments of the present disclosure.

FIG. 4 is an example cross-sectional view taken along line A-A′ of FIG. 3.

FIG. 5 is an example cross-sectional view taken along line B-B′ of FIG. 3.

FIG. 6 is an example cross-sectional view taken along line C-C′ of FIG. 3.

FIG. 7 is an enlarged view of portion P in FIG. 4.

FIG. 8 is an enlarged view of portion Q in FIG. 7.

FIG. 9 is a perspective view illustrating a capping film, a second source/drain region, and an inner insulating film of FIG. 8.

FIG. 10 is a perspective view for explaining the capping film of FIG. 8.

FIGS. 11 and 12 are cross-sectional views for explaining capping films according to some example embodiments of the present disclosure.

FIGS. 13 through 30 are diagrams illustrating a method of manufacturing a semiconductor memory device according to some example embodiments of the present disclosure.

### DETAILED DESCRIPTION

Although terms such as first, second, upper, and lower are used to describe various devices or components in this specification, these devices and/or components are not limited by these terms. These terms are merely used to distinguish one device or component from another. Therefore, a first device or component mentioned below may be a second device or component within the technical scope of the present disclosure. Likewise, a lower device or component mentioned below may be an upper device or component within the technical scope of the present disclosure.

As used herein, expressions such as “one of,” “any one of,” and “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Some example embodiments of the present disclosure will hereinafter be described in detail with reference to the accompanying drawings. The same reference numerals will be used for the same components in the drawings, and redundant descriptions of such components will be omitted.

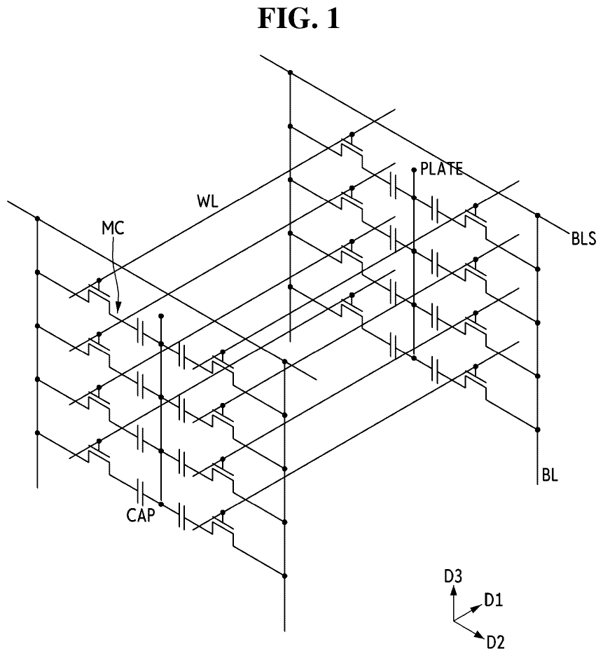

FIG. 1 is an example circuit diagram illustrating a cell array of a semiconductor memory device according to some example embodiments of the present disclosure.

Referring to FIG. 1, the semiconductor memory device may include a plurality of memory cells MC arranged along a second direction D2 and a third direction D3. Each of the memory cells MC may include a memory cell transistor and a data storage element CAP that are arranged along the second direction D2 and connected to each other.

Bitlines BL may be conductive patterns (e.g., metallic conductive lines) extending in a direction perpendicular to a substrate (e.g., the third direction D3). The bitlines BL may be arranged along the second direction D2. Adjacent bitlines BL may be spaced apart from each other along the second direction D2.

In some example embodiments, some of the bitlines BL may be connected by bitline strapping lines BLS. For example, the bitline strapping lines BLS may connect bitlines BL arranged along the second direction D2.

Wordlines WL may be conductive patterns (e.g., metallic conductive lines) stacked in the third direction D3 on the substrate. The wordlines WL may extend in a first direction D1. Adjacent wordlines WL may be spaced apart from each other in the third direction D3.

Data storage elements CAP may be commonly connected to plate electrodes PLATE extending in the first and third directions D1 and D3. In some example embodiments, plate electrodes PLATE arranged along the first direction D1 may form an integral structure.

Data storage elements CAP and memory cell transistors arranged along the second direction D2 may be symmetrically disposed with respect to a plane extending in the first and third directions D1 and D3 where the plate electrodes PLATE are disposed.

The gates of the memory cell transistors may be connected to the wordlines WL, and the first sources/drains of the memory cell transistors may be connected to the bitlines BL. The second sources/drains of the memory cell transistors may be connected to the data storage elements CAP. For example, the data storage elements CAP may be capacitors. The second sources/drains of the memory cell transistors may be connected to the storage electrodes of the capacitors.

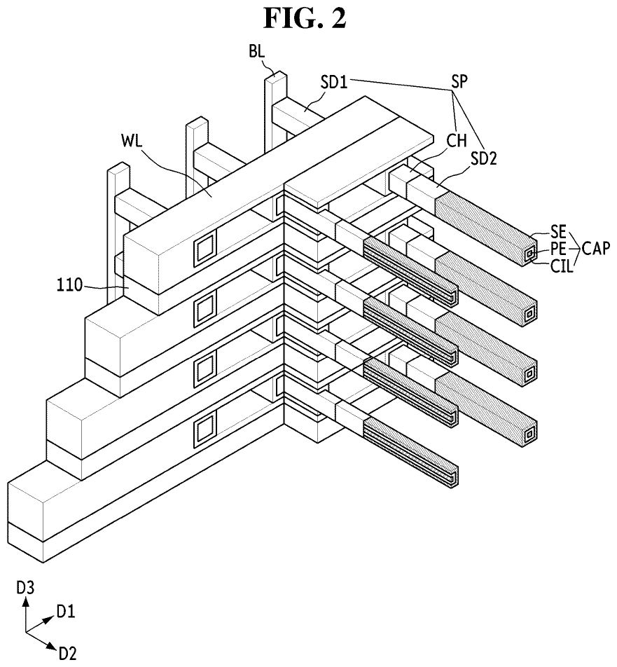

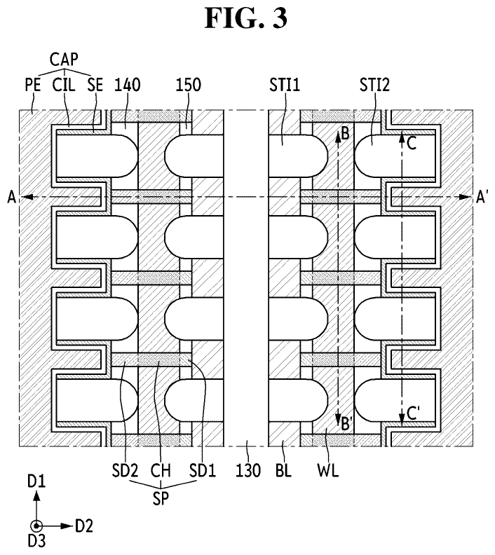

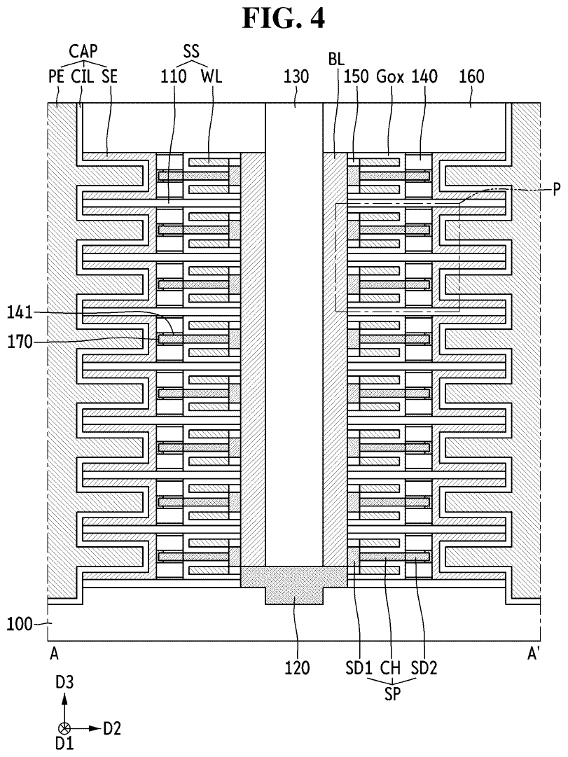

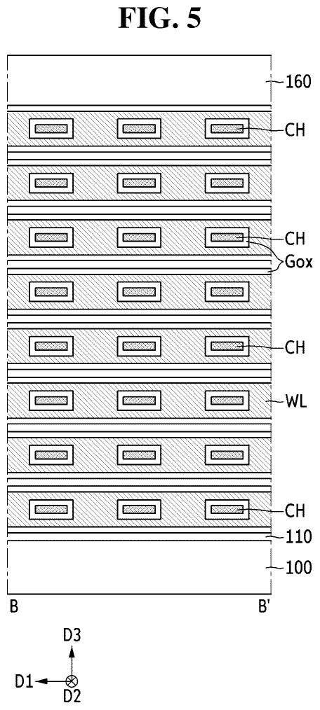

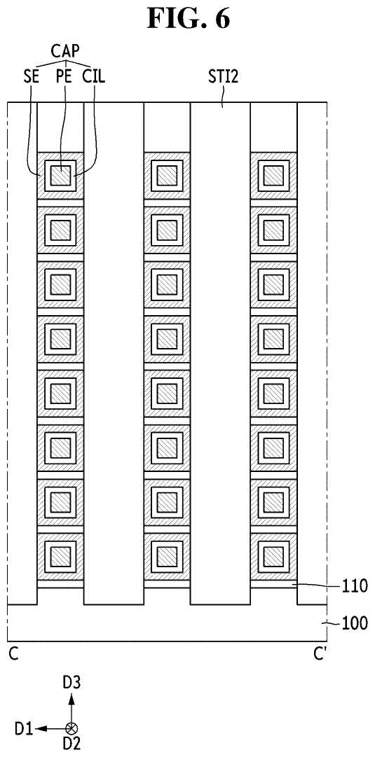

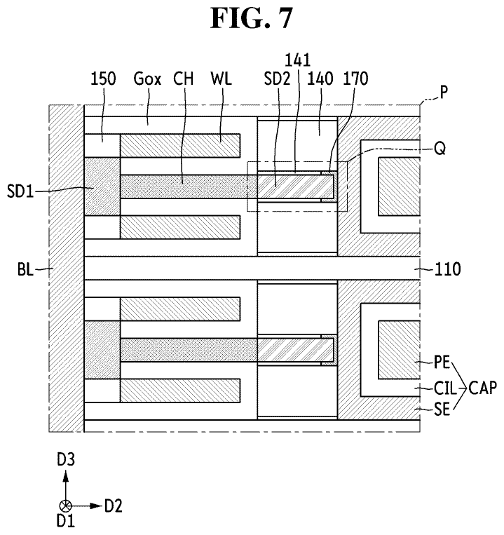

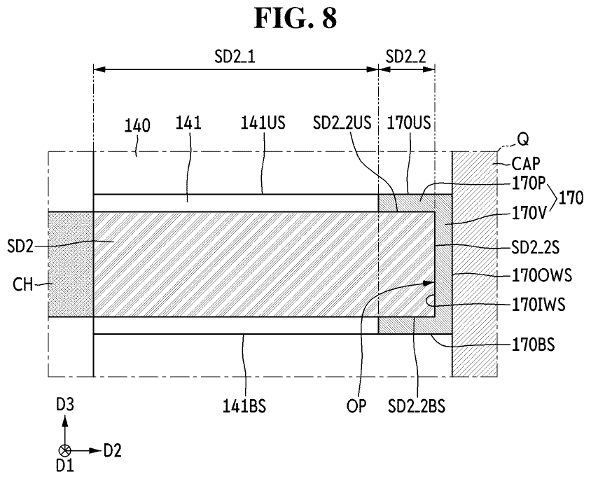

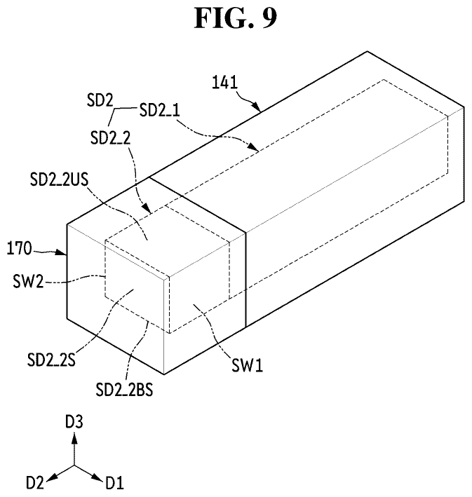

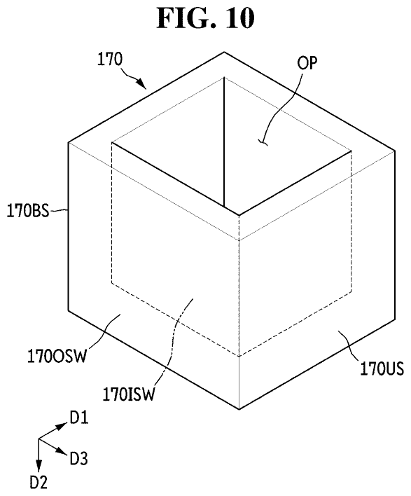

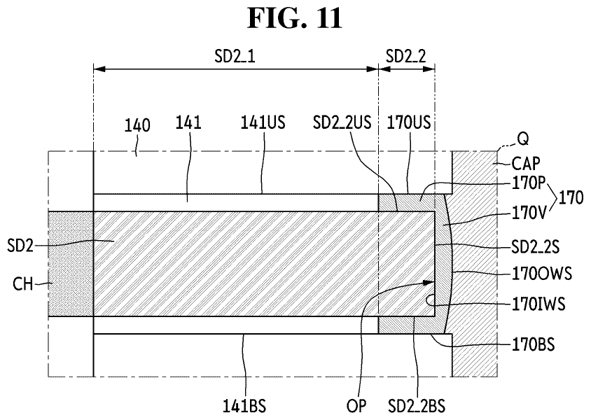

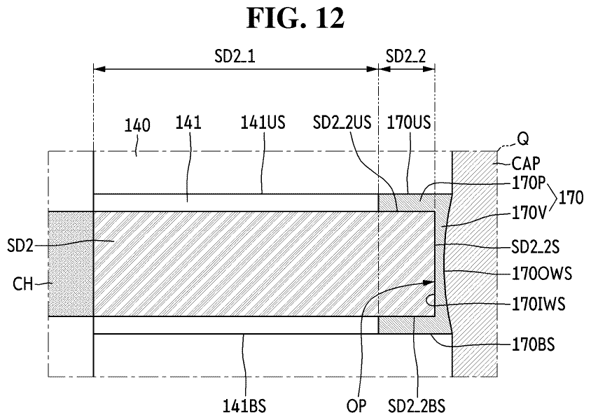

FIG. 2 is an example perspective view illustrating a semiconductor memory device according to some example embodiments of the present disclosure. FIG. 3 is an example plan view illustrating a semiconductor memory device according to some example embodiments of the present disclosure. FIG. 4 is an example cross-sectional view taken along line A-A′ of FIG. 3. FIG. 5 is an example cross-sectional view taken along line B-B′ of FIG. 3. FIG. 6 is an example cross-sectional view taken along line C-C′ of FIG. 3. FIG. 7 is an enlarged view of portion P in FIG. 4. FIG. 8 is an enlarged view of portion Q in FIG. 7. FIG. 9 is a perspective view illustrating a capping film, a second source/drain region, and an inner insulating film of FIG. 8. FIG. 10 is a perspective view for explaining the capping film of FIG. 8. FIGS. 11 and 12 are cross-sectional views for explaining capping films according to some example embodiments of the present disclosure.

Referring to FIGS. 2 through 12, the semiconductor memory device may include a substrate 100, a stacked structure SS, a semiconductor pattern SP, bitlines BL, data storage elements CAP, a capping film 170, and an inner insulating film 141.

The upper surface of the substrate 100 may be disposed on a plane extending along first and second directions D1 and D2. The upper surface of the substrate 100 may be perpendicular to a third direction D3. In this specification, the first, second, and third directions D1, D2, and D3 may intersect each other. The first, second, and third directions D1, D2, and D3 may be substantially perpendicular to each other.

The substrate 100 may be a bulk silicon (Si) or silicon-on-insulator (SOI) substrate. In some example embodiments, the substrate 100 may be an Si substrate, or may include other materials, for example, silicon-germanium (SiGe), SiGe-on-insulator (SGOI), indium antimonide, a lead telluride compound, indium arsenide, indium phosphide, gallium arsenide, or gallium antimonide, but the present disclosure is not limited to these.

The stacked structure SS may be disposed on the substrate 100. The stacked structure SS may include a plurality of interlayer insulating films 110 and a plurality of wordlines WL. The interlayer insulating films 110 and the wordlines WL may be alternately and repeatedly stacked in the third direction D3. For example, two wordlines WL may be disposed between adjacent interlayer insulating films 110 in the third direction D3.

Each of the wordlines WL may include a line portion extending in the first direction D1 in parallel to the upper surface of the substrate 100 and a gate electrode portion protruding in the second direction D2. Here, the line portions of the wordlines WL may be provided between first isolation insulating patterns STI1 and second isolation insulating patterns STI2, which are spaced apart from corresponding ones of the first isolation insulating patterns STI1, respectively. That is, the line portions may overlap with the first isolation insulating patterns STI1 and the second isolation insulating patterns STI2 in the second direction D2. The gate electrode portions of the wordlines WL may not overlap with the first isolation insulating patterns STI1 or the second isolation insulating patterns STI2 in the second direction D2. From a planar view, a pair of wordlines WL may be symmetrical with respect to a vertical insulating pattern 130, which will be described later.

The wordlines WL may include a conductive material. For example, the wordlines WL may include at least one of a doped semiconductor material (e.g., doped Si, doped SiGe or doped germanium (Ge)), conductive metal nitride (e.g., titanium nitride or tantalum nitride), metal (e.g., tungsten, titanium, or tantalum), or a metal-semiconductor compound (e.g., tungsten silicide, cobalt silicide, or titanium silicide), but the present disclosure is not limited thereto.

The interlayer insulating films 110 may be provided between adjacent wordlines WL in the third direction D3. The interlayer insulating films 110 may electrically isolate the wordlines WL. Some of the interlayer insulating films 110 may also electrically isolate data storage elements CAP. The interlayer insulating films 110 may overlap with the data storage elements CAP in the third direction D3. The interlayer insulating films 110 may contact storage electrodes SE of the data storage elements CAP. The interlayer insulating films 110 may contact capacitor dielectric films CIL of the data storage elements CAP. Still some of the interlayer insulating films 110 may contact gate insulating films Gox, and the bitlines BL.

The interlayer insulating films 110 may include an insulating material. For example, the interlayer insulating films 110 may include at least one of silicon oxide films, silicon nitride films, silicon oxynitride films, carbon (Ca)-containing silicon oxide films, Ca-containing silicon nitride films, or Ca-containing silicon oxynitride films. For example, the interlayer insulating films 110 may include silicon oxide films.

Semiconductor patterns SP may be disposed between corresponding pairs of the adjacent wordlines WL in the third direction D3, respectively. The semiconductor patterns SP may extend in the second direction D2. The semiconductor patterns SP may each have first and second terminals spaced apart in the second direction D2. The first terminals of the semiconductor patterns SP may be connected to the bitlines BL. The second terminals of the semiconductor patterns SP may be connected to the data storage elements CAP, which will be described later.

The semiconductor patterns SP may each include a channel region CH, a first source/drain region SD1, and a second source/drain regions SD2.

The channel regions CH of the semiconductor patterns SP may be stacked in the third direction D3. The channel regions CH of the semiconductor patterns SP may be provided between corresponding pairs of the adjacent wordlines WL in the third direction D3, respectively. For example, if three wordlines WL including first, second, and third wordlines are provided, the channel regions CH may be provided between the first and second wordlines, and an interlayer insulating film 110 may be provided between the second and third wordlines. However, the present disclosure is not limited to this example.

The channel regions CH may be spaced apart in the first and third directions D1 and D3. The channel regions CH may extend in the second direction D2. That is, the channel regions CH may be arranged three-dimensionally on the substrate 100. The channel regions CH may include at least one of Si or Ge. For example, the channel regions CH may include monocrystalline Si.

The channel regions CH may have a bar shape with a long axis extending in the second direction D2. The channel regions CH may penetrate the wordlines WL in the second direction D2. The wordlines WL may have a structure (e.g., a gate-all-around structure) that completely surrounds the channel regions CH. The gate insulating films Gox may be interposed between the channel regions CH and the wordlines WL. The gate insulating films Gox may contact capping insulating films 150, which will be described later, and spacer insulating films 140, which will also be described later. The gate insulating films Gox may contact interlayer insulating films 110.

The gate insulating films Gox may include at least one of high-k dielectric films, silicon oxide films, silicon nitride films, or silicon oxynitride films. For example, the high-k dielectric films may include at least one of hafnium oxide, hafnium silicon oxide, lanthanum oxide, zirconium oxide, zirconium silicon oxide, tantalum oxide, titanium oxide, barium strontium titanate, barium titanate, strontium titanate, lithium oxide, aluminum oxide, lead scandium tantalate, or lead zinc niobate.

The first source/drain regions SD1 may be disposed on first sides of the channel regions CH. The second source/drain regions SD2 may be disposed on second sides of the channel regions CH. The first source/drain regions SD1 and the second source/drain regions SD2 may be disposed with the channel regions CH in between. The first source/drain regions SD1 and the second source/drain regions SD2 may each include Si doped with impurities. For example, the first source/drain regions SD1 and the second source/drain regions SD2 may each include SiP or SiAs, but the present disclosure is not limited thereto.

In some example embodiments, the impurity concentration in the first source/drain regions SD1 may be higher than that in the second source/drain regions SD2. This may be because the first source/drain regions SD1 are formed using a selective epitaxial growth (SEG) process, while the second source/drain regions SD2 are formed using an ion doping process.

The first source/drain regions SD1 may be connected to the bitlines BL. The second source/drain regions SD2 may be connected to the data storage elements CAP. For example, the second source/drain regions SD2 may be electrically connected to the storage electrodes SE of the data storage elements CAP.

The second source/drain regions SD2 may include first portions SD2_1 and second portions SD2_2. The first portions SD2_1 may be closer than the second portions SD2_2 to the channel regions CH. The second portions SD2_2 may be closer than the first portions SD2_1 to the data storage elements CAP.

Inner insulating films 141 may be disposed on the second source/drain regions SD2. The inner insulating films 141 may surround parts of the second source/drain regions SD2. The inner insulating films 141 may cover the first portions SD2_1 of the second source/drain regions SD2.

The inner insulating films 141 may include an insulating material. For example, the inner insulating films 141 may include at least one of silicon oxide films, silicon nitride films, silicon oxynitride films, Ca-containing silicon oxide films, Ca-containing silicon nitride films, or Ca-containing silicon oxynitride films.

Capping films 170 may be disposed on the second source/drain regions SD2. The capping films 170 may surround parts of the second source/drain regions SD2. The capping films 170 may cover the second portions SD2_2 of the second source/drain regions SD2.

The capping films 170 may extend in the third direction D3 and may each include a vertical portion 170V that contacts the data storage elements CAP, and protruding portions 170P that protrude from the vertical portion 170V in the second direction D2. The capping films 170 may include insertion holes OP. The insertion holes OP may be defined by the vertical portions 170V and protruding portions 170P of the capping films 170.

The insertion holes OP may be open in the second direction D2. The insertion holes OP may be surrounded by the protruding portions 170P and may not be open in the second direction D2 or the third direction D3.

At least portions of the second source/drain regions SD2 may be inserted into the insertion holes OP. For example, the second portions SD2_2 of the second source/drain regions SD2 may be inserted into the insertion holes OP. The portions of the second source/drain regions SD2 inserted into the insertion holes OP may not be exposed. The second portions SD2_2 of the second source/drain regions SD2 inserted into the insertion hole OP may not be exposed in the second direction D2 or the third direction D3. The portions of the second source/drain regions SD2 inserted into the insertion holes OP may contact the capping films 170.

The second portions SD2_2 of the second source/drain regions SD2 may include first surfaces SD2_2S that contact the capping films 170, upper surfaces SD2_2US and lower surfaces SD2_2BS that are opposite to each other in the third direction D3, and first side surfaces SW1 and second side surfaces SW2 that are opposite to each other in the first direction D1. The capping films 170 may contact the first surfaces SD2_2S, upper surfaces SD2_2US, lower surfaces SD2_2BS, first side surfaces SW1, and second side surfaces SW2 of the second portions SD2_2. That is, the capping films 170 may cover all the surfaces of the second portions SD2_2 of the second source/drain regions SD2. The capping films 170 may completely surround the second portions SD2_2 of the second source/drain regions SD2.

The vertical portions 170V of the capping films 170 may be disposed on the first surfaces SD2_2S of the second portions SD2_2. The protruding portions 170P of the capping films 170 may be disposed on the upper surfaces SD2_2US, lower surfaces SD2_2BS, first side surfaces SW1, and second side surfaces SW2 of the second portions SD2_2. The vertical portions 170V of the capping films 170 may contact the first surfaces SD2_2S of the second portions SD2_2. The protruding portions 170P of the capping films 170 may contact the upper surfaces SD2_2US, lower surfaces SD2_2BS, first side surfaces SW1, and second side surfaces SW2 of the second portions SD2_2.

In some example embodiments, the second source/drain regions SD2 may include Si.

In this case, the capping films 170 may include metal silicide, for example, at least one of molybdenum (Mo) silicide, titanium (Ti) silicide, cobalt (Co) silicide, nickel (Ni) silicide, nickel-platinum (NiPt) silicide, ruthenium (Ru) silicide, or zirconium (Zr) silicide.

In some example embodiments, the second source/drain regions SD2 may include an oxide semiconductor. The oxide semiconductor may include, for example, one of indium gallium zinc oxide (IGZO), impurity-doped indium zinc oxide (IZO), indium oxide (InO), zinc oxide (ZnO), gallium oxide (GaO), tin oxide (SnO), aluminum zinc oxide (AZO), or indium tin oxide (ITO). The impurities in the impurity-doped IZO may include at least one of magnesium (Mg), strontium (Sr), barium (Ba), scandium (Sc), yttrium (Y), lanthanum (La), titanium (Ti), zirconium (Zr), hafnium (Hf), aluminum (Al), tin (Sn), or tantalum (Ta).

In this case, the capping films 170 may include at least one of indium oxide (InOₓ), ITO, ruthenium oxide (RuOₓ), molybdenum oxide (MoOₓ), titanium nitride (TiN), Mo, or Ru.

In some example embodiments, the second source/drain regions SD2 may include a two-dimensional (2D) material, for example, MoS₂ or WSe₂, but the present disclosure is not limited thereto.

In this case, the capping films 170 may include at least one of antimony (Sb), antimony telluride (Sb₂Te₃), palladium/nickel (Pd/Ni), nickel/gold (Ni/Au), Ti, chromium (Cr), palladium (Pd), gold (Au), platinum (Pt), silver (Ag), copper (Cu), Ni, or cobalt (Co).

The capping films 170 may be disposed between the inner insulating films 141 and the data storage elements CAP. The inner insulating films 141 may be disposed on the capping films 170. The inner insulating films 141 may contact the protruding portions 170P of the capping films 170.

The capping films 170 and the inner insulating films 141 may surround the second source/drain regions SD2. For example, the first portions SD2_1 of the second source/drain regions SD2 may be covered by the inner insulating films 141. The second portions SD2_2 of the second source/drain regions SD2 may be covered by the capping films 170. The second source/drain regions SD2 surrounded by the inner insulating films 141 and the capping films 170 may not be exposed.

Upper surfaces 141US of the inner insulating films 141 and upper surfaces 170US of the capping films 170 may be on the same plane. Lower surfaces 141BS of the inner insulating films 141 and lower surfaces 170BS of the capping films 170 may be on the same plane. For example, based on the upper surfaces of the second source/drain regions SD2, the height of the upper surfaces 141US of the inner insulating films 141 and the height of the upper surfaces 170US of the capping films 170 may be the same. Based on the lower surfaces of the second source/drain regions SD2, the height of the lower surfaces 141BS of the inner insulating films 141 and the height of the lower surfaces 170BS of the capping films 170 may be the same.

The capping films 170 may be disposed between the second source/drain regions SD2 and the data storage elements CAP. The capping films 170 may connect the second source/drain regions SD2 and the data storage elements CAP.

The capping films 170 may include outer walls 170OWS and inner walls 170IWS. The outer walls 170OWS of the capping films 170 may contact the data storage elements CAP. The inner walls 170IWS of the capping films 170 may contact the second source/drain regions SD2. The widths, in the third direction D3, of the inner walls 170IWS of the capping films 170 may be smaller than the widths, in the third direction D3, of the outer walls 170OWS of the capping films 170. The widths, in the third direction D3, of the outer walls 170OWS of the capping films 170 may be smaller than the widths, in the third direction D3, of the data storage elements CAP.

The surfaces connecting the outer walls 170OWS, upper surfaces 170US, and lower surfaces 170BS of the capping films 170 may be convex with respect to the data storage elements CAP. The surfaces connecting the inner walls 170IWS, upper surfaces, and lower surfaces of the protruding portions 170P of the capping films 170 may be concave with respect to the data storage elements CAP.

Referring to FIG. 11, in some example embodiments, the outer walls 170OWS of the capping films 170 may be convex toward the data storage elements CAP. In some example embodiments, referring to FIG. 12, in some example embodiments, the outer walls 170OWS of the capping films 170 may be concave toward the data storage elements CAP. However, the shape of the capping films 170 is not limited to these examples.

The capping insulating films 150 may be provided between the bitlines BL and the wordlines WL. The capping insulating films 150 may be provided between the first source/drain regions SD1 and the interlayer insulating films 110. The capping insulating films 150 may electrically isolate the bitlines BL from the wordlines WL. The capping insulating films 150 may surround the first source/drain regions SD1. The capping insulating films 150 may be in direct contact with the wordlines WL. The capping insulating films 150 may be in direct contact with the first source/drain regions SD1, but the present disclosure is not limited thereto.

The capping insulating films 150 may include at least one of silicon oxide films, silicon nitride films, silicon oxynitride films, Ca-containing silicon oxide films, Ca-containing silicon nitride films, or Ca-containing silicon oxynitride films. For example, the capping insulating films 150 may be formed of or include silicon nitride.

The spacer insulating films 140 may be provided between the wordlines WL and the data storage elements CAP. The spacer insulating films 140 may be disposed between the second source/drain regions SD2 and the interlayer insulating films 110. The spacer insulating films 140 may be spaced apart from the wordlines WL with the gate insulating films Gox in between. In some example embodiments, the spacer insulating films 140 may be formed as a multilayer film. For example, if the spacer insulating films 140 are formed as a multilayer, film, the spacer insulating films 140 may include liner films and filling films. The liner films may surround the second source/drain regions SD2 and the interlayer insulating films 110. The filling films may fill the trenches defined by the liner films, the gate insulating films Gox, and the storage electrodes SE.

The spacer insulating films 140 may include, for example, at least one of silicon oxide films, silicon nitride films, silicon oxynitride films, Ca-containing silicon oxide films, Ca-containing silicon nitride films, or Ca-containing silicon oxynitride films.

The semiconductor memory device may further include the first isolation insulating patterns STI1, the second isolation insulating patterns STI2, a lower protective pattern 120, the vertical insulating pattern 130, and an upper insulating film 160.

The lower protective pattern 120 may be provided on the substrate 100. The lower protective pattern 120 may be provided between the substrate 100 and the bitlines BL. The lower protective pattern 120 may overlap wordlines WL closest to the substrate 100 in the second direction D2. The lower protective pattern 120 may be formed of or include the same material as the capping insulating films 150, but the present disclosure is not limited thereto.

The vertical insulating pattern 130 may be disposed on the lower protective pattern 120. The vertical insulating pattern 130 may be disposed on the bitlines BL. Although not illustrated, the vertical insulating pattern 130 may be provided between the bitlines BL. The vertical insulating pattern 130 may extend in the third direction D3 from the lower protective pattern 120. The vertical insulating pattern 130 may cover the sidewalls of the bitlines BL and the sidewalls of the first isolation insulating patterns STI1.

The upper insulating film 160 may be formed on the stacked structure SS. The upper insulating film 160 may be provided between the plate electrodes PE and the vertical insulating pattern 130. The upper insulating film 160 may be disposed on uppermost wordline WL. The upper insulating film 160 may be formed of or include a silicon oxide film, but the present disclosure is not limited thereto.

The first isolation insulating patterns STI1 may be provided between the wordlines WL and the vertical insulating pattern 130. The first isolation insulating patterns STI1 may be provided between the bitlines BL. The second isolation insulating patterns STI2 may be provided between the wordlines WL and the data storage elements CAP. The second isolation insulating patterns STI2 may be provided between the storage electrodes SE. The first isolation insulating patterns STI1 and the second isolation insulating patterns STI2 may each be formed of or include an insulating material. For example, the first isolation insulating patterns STI1 and the second isolation insulating patterns STI2 may each be formed of or include silicon oxide films.

The data storage elements CAP may be connected to the capping films 170. In some example embodiments, the data storage elements CAP may be capacitors.

The data storage elements CAP may include the storage electrodes SE, the plate electrodes PE, and the capacitor dielectric films CIL. The data storage elements CAP may share the capacitor dielectric films CIL and the plate electrodes PE. That is, a plurality of storage electrodes SE connected to corresponding ones of the second source/drain regions SD2, respectively, may be provided, and a single capacitor dielectric film CIL may cover the surfaces of the plurality of storage electrodes SE. A single plate electrode PE may cover the single capacitor dielectric film CIL. Here, the plate electrodes PE may be the same as the plate electrodes PLATE in FIG. 1. That is, the data storage elements CAP may be defined by the storage electrodes SE.

The storage electrodes SE may have closed first portions facing the second source/drain regions SD2 and open second portions opposite to the first portions, and may thereby have a hollow cylindrical shape. In other words, the storage electrodes SE may have a 90 degrees-rotated U shape. The storage electrodes SE may be electrically connected to the second source/drain regions SD2. The storage electrodes SE may, for example, be in direct contact with the capping films 170.

The storage electrodes SE and the plate electrodes PE may each include, for example, a doped semiconductor material, conductive metal nitride (e.g., titanium nitride, tantalum nitride, niobium nitride, or tungsten nitride), metal (e.g., ruthenium, iridium, titanium, niobium, tungsten, cobalt, molybdenum, or tantalum), or conductive metal oxide (e.g., iridium oxide or niobium oxide), but the present disclosure is not limited thereto. For example, the storage electrodes SE may include conductive metal nitride, metal, and conductive metal oxide. The conductive metal nitride, the metal, and the conductive metal oxide may be included in metallic conductive films (e.g., may be collectively referred to as metallic conductive films).

The capacitor dielectric films CIL may include, for example, a high-k material (e.g., hafnium oxide, hafnium silicon oxide, lanthanum oxide, zirconium oxide, zirconium silicon oxide, tantalum oxide, titanium oxide, barium strontium titanate, barium titanate, strontium titanate, lithium oxide, aluminum oxide, lead scandium tantalate, lead zinc niobate, or a combination thereof). In some example embodiments, the capacitor dielectric films CIL may include a laminated film structure where zirconium oxide, aluminum oxide, and zirconium oxide are sequentially stacked. In some example embodiments, the capacitor dielectric films CIL may include Hf.

A three-dimensional (3D) semiconductor memory device has a very small contact area between semiconductors and metals, resulting in relatively high contact resistance. When the contact resistance is high, the characteristics of the semiconductor memory device may deteriorate.

However, in the semiconductor memory device according to some example embodiments of the present disclosure, the capping films 170 may be disposed between the second source/drain regions SD2 and the data storage elements CAP. The capping films 170 may include the insertion holes OP. Portions of the second source/drain regions SD2 may be inserted into the insertion holes OP of the capping films 170. Because contact resistance is inversely proportional to the contact area, the contact resistance may decrease as the contact area increases. The capping films 170 may contact the first surfaces SD2_2S, the upper surfaces SD2_2US, the lower surfaces SD2_2BS, the first side surfaces SW1, and the second side surfaces SW2 of the second source/drain regions SD2. The capping films 170 may form an all-around contact structure that surrounds all surfaces of the second portions SD2_2 of the second source/drain regions SD2. Accordingly, the contact resistance between the capping films 170 and the second source/drain regions SD2 may be improved, thereby improving the contact resistance between the semiconductor patterns SP and the data storage elements CAP.

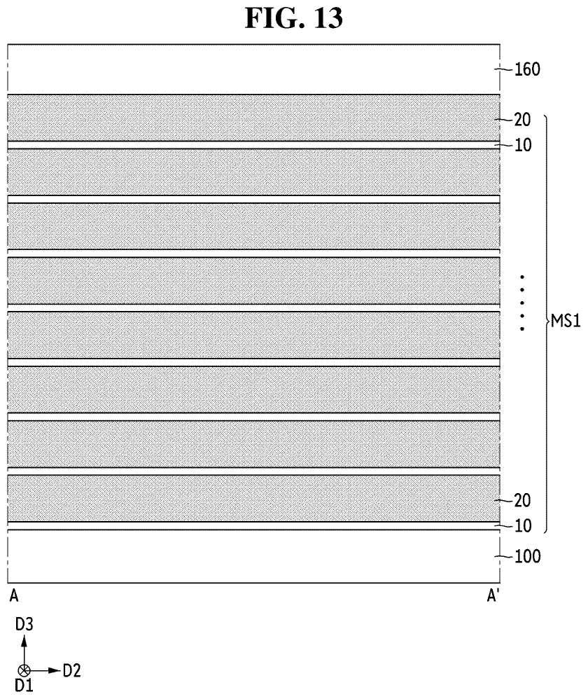

A method of manufacturing a semiconductor memory device according to some example embodiments of the present disclosure will hereinafter be described with reference to FIGS. 13 through 30.

FIGS. 13 through 30 are diagrams illustrating a method of manufacturing a semiconductor memory device according to some example embodiments of the present disclosure. For the convenience of explanation, content that overlaps with that described with reference to FIGS. 1 through 12 will be briefly explained or omitted.

Referring to FIG. 13, a substrate 100 may be provided. A first mold structure MS1 may be formed on the substrate 100.

The first mold structure MS1 may include first sacrificial films 10 and semiconductor films 20. The first mold structure MS1 may be formed by alternately stacking the first sacrificial films 10 and the semiconductor films 20. For example, the first sacrificial films 10 may be formed between adjacent semiconductor films 20 in a third direction D3, and the semiconductor films 20 may be formed between adjacent first sacrificial films 10 in the third direction D3. The thickness of the first sacrificial films 10 may be smaller than the thickness of the semiconductor films 20.

The first sacrificial films 10 may be formed of or include a material having an etch selectivity with respect to the semiconductor films 20. For example, the first sacrificial films 10 may be formed of or include at least one of SiGe, Ca-doped SiGeC, silicon oxide, silicon nitride, or silicon oxynitride.

The semiconductor films 20 may be formed of, for example, Si, Ge, SiGe, a 2D semiconductor material, or IGZO. In some example embodiments, the semiconductor films 20 may be formed of or include the same material as the substrate 100. For example, the semiconductor films 20 may be monocrystalline Si films or polycrystalline Si films.

In some example embodiments, the first sacrificial films 10 and the semiconductor films 20 may be formed using an epitaxial growth process. For example, the semiconductor films 20 may be monocrystalline Si films, and the first sacrificial films 10 may be SiGe films having a superlattice structure.

An upper insulating film 160 may be formed on the first mold structure MS1. The upper insulating film 160 may cover the semiconductor film 20 positioned at a highest vertical level among the semiconductor films 20. The upper insulating film 160 may be formed of or include an insulating material having an etch selectivity with respect to the first sacrificial films 10 and the semiconductor films 20. For example, the upper insulating film 160 may be formed of or include silicon oxide.

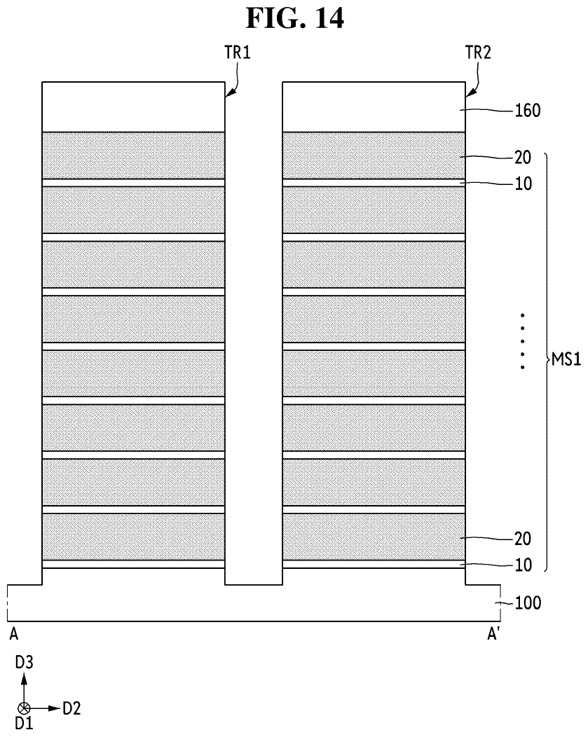

Referring to FIG. 14, a first trench TR1 and second trenches TR2 may be formed through the first mold structure MS1. The first trench TR1 and the second trenches TR2 may each expose the sidewalls of the first sacrificial films 10 and the sidewalls of the semiconductor films 20.

Forming the first trench TR1 and the second trenches TR2 may involve forming a mask pattern having openings corresponding to the first trench TR1 and the second trenches TR2 on the first mold structure MS1, and etching the first mold structure MS1 using the mask pattern as an etch mask.

The first trench TR1 and the second trenches TR2 may expose the upper surface of the substrate 100, and during etching, the upper surface of the substrate 100 below the first trench TR1 and the second trenches TR2 may be recessed due to over-etching, thereby forming recessed regions.

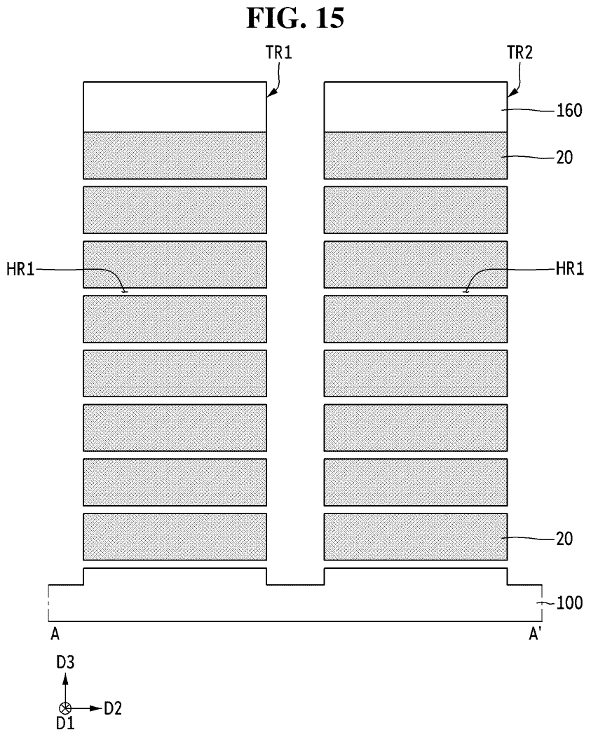

Referring to FIG. 15, the exposed first sacrificial films 10 may be removed through the first trench TR1 and the second trenches TR2.

First horizontal regions HR1 may be formed between the adjacent semiconductor films 20 in a vertical direction (e.g., the third direction D3). Forming the first horizontal regions HR1 may involve performing an etching process that has an etch selectivity with respect to the substrate 100 and the semiconductor films 20 to isotropically etch the first sacrificial films 10. When removing the first sacrificial films 10, the semiconductor films 20 may remain spaced apart from each other in the third direction D3 without collapsing.

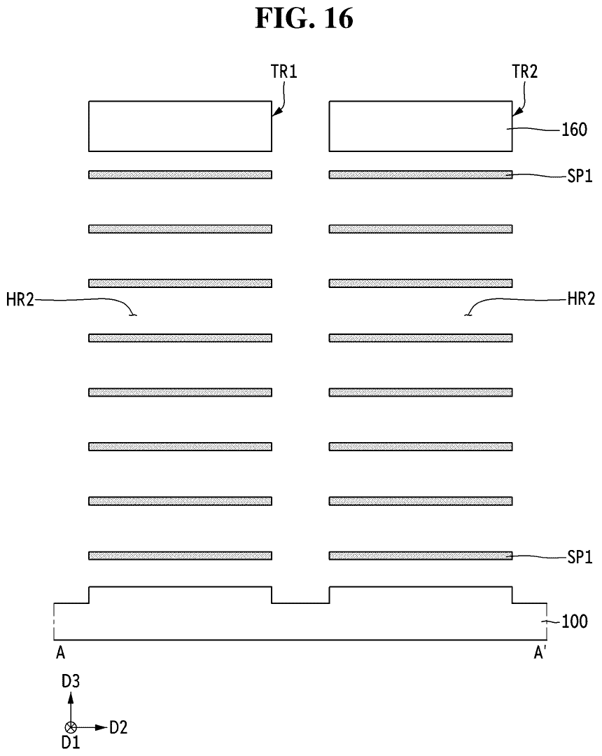

Referring to FIG. 16, an enlargement process may be performed to increase the thickness of the first horizontal regions HR1 in the third direction D3. For example, the enlargement process may include etching the upper surfaces and lower surfaces of the semiconductor films 20 exposed by the first horizontal regions HR1. The enlargement process may involve performing an isotropic etching process with an etch selectivity with respect to the upper insulating film 160. The thickness of the semiconductor films 20 may be reduced by the enlargement process. Accordingly, first semiconductor patterns SP1 may be formed, and second horizontal regions HR2 may be formed between corresponding pairs of adjacent first semiconductor patterns SP1 in the third direction D3, respectively.

In some example embodiments, an oxidation process may be performed on the first semiconductor patterns SP1, thereby forming sacrificial oxide films on the surfaces of the first semiconductor patterns SP1. Thereafter, the sacrificial oxide films may be removed, exposing the surfaces of the first semiconductor patterns SP1 again. After removing the sacrificial oxide films, the distance between the adjacent first semiconductor patterns SP1 in the third direction D3 may be increased. That is, the second horizontal regions HR2 may be further enlarged in the vertical direction.

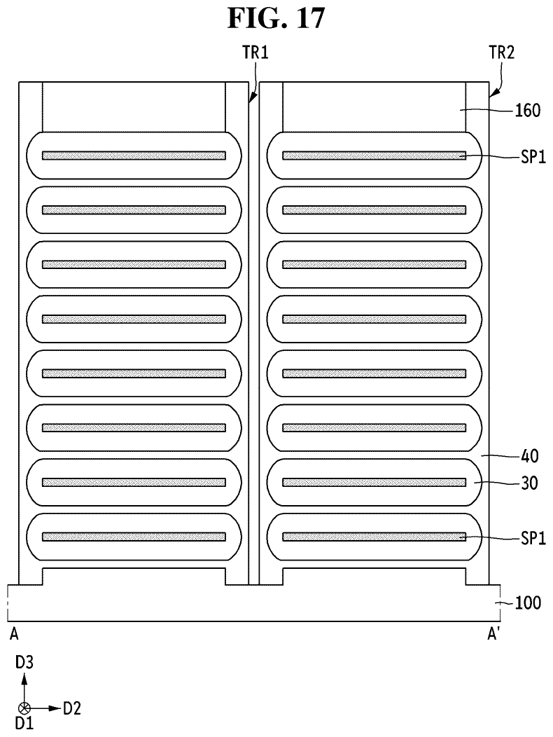

Referring to FIG. 17, second sacrificial films 30 and pre-interlayer insulating films 40 may be formed on the surfaces of the first semiconductor patterns SP1. The second sacrificial films 30 and the pre-interlayer insulating films 40 may be sequentially deposited.

The second sacrificial films 30 may include a material having an etch selectivity with respect to the substrate 100 and the first semiconductor patterns SP1. For example, the second sacrificial films 30 may be formed of or include at least one of silicon oxide, silicon nitride, or silicon oxynitride. The second sacrificial films 30 may be formed by atomic layer deposition (ALD) or chemical vapor deposition (CVD).

The second sacrificial films 30 may be deposited to surround the respective first semiconductor patterns SP1. Accordingly, after depositing the second sacrificial films 30, gap regions may be defined between the adjacent first semiconductor patterns SP1 in the third direction D3.

Thereafter, the pre-interlayer insulating films 40 may be formed on the second sacrificial films 30 to fill the second horizontal regions HR2 where the second sacrificial films 30 have been formed. The pre-interlayer insulating films 40 may be formed of or include an insulating material having an etch selectivity with respect to the second sacrificial films 30 and the substrate 100. For example, the pre-interlayer insulating films 40 may be formed of or include silicon oxide.

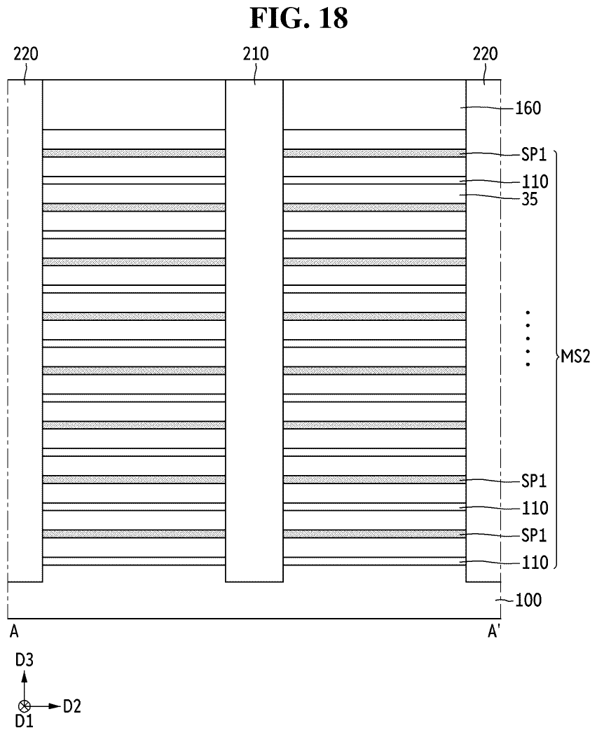

Referring to FIG. 18, by etching the pre-interlayer insulating films 40 and the second sacrificial films 30, a second mold structure MS2 may be formed. The second mold structure MS2 may include a plurality of interlayer insulating films 110, a plurality of first semiconductor patterns SP1, and a plurality of second sacrificial patterns 35.

For example, the interlayer insulating films 110 may be formed by etching portions of the pre-interlayer insulating films 40. The interlayer insulating films 110 may be formed by isotropically etching the pre-interlayer insulating films 40 until the second sacrificial films 30 are exposed in the first trench TR1 and the second trenches TR2. The interlayer insulating films 110 may be separated from each other in the third direction D3.

After forming the interlayer insulating films 110, portions of the second sacrificial films 30 may be etched to form the second sacrificial patterns 35. The second sacrificial patterns 35 may be formed by isotropically etching the second sacrificial films 30 until the first semiconductor patterns SP1 are exposed. The second sacrificial patterns 35 may be separated from each other in the third direction D3. The first semiconductor patterns SP1 may be disposed between the second sacrificial patterns 35.

After forming the second mold structure MS2, a first buried insulating pattern 210 and second buried insulating patterns 220, filling the first trench TR1 and the second trenches TR2, may be formed. Forming the first buried insulating pattern 210 and the second buried insulating patterns 220 may involve forming a buried insulating film to fill the first trench TR1 and the second trenches TR2 and planarizing the buried insulating film to expose the upper surface of the upper insulating film 160. The first buried insulating pattern 210 and the second buried insulating patterns 220 may each be formed of or include at least one of silicon oxide, silicon nitride, or silicon oxynitride. The first buried insulating pattern 210 and the second buried insulating patterns 220 may each be formed as a single-layer or a multilayer film.

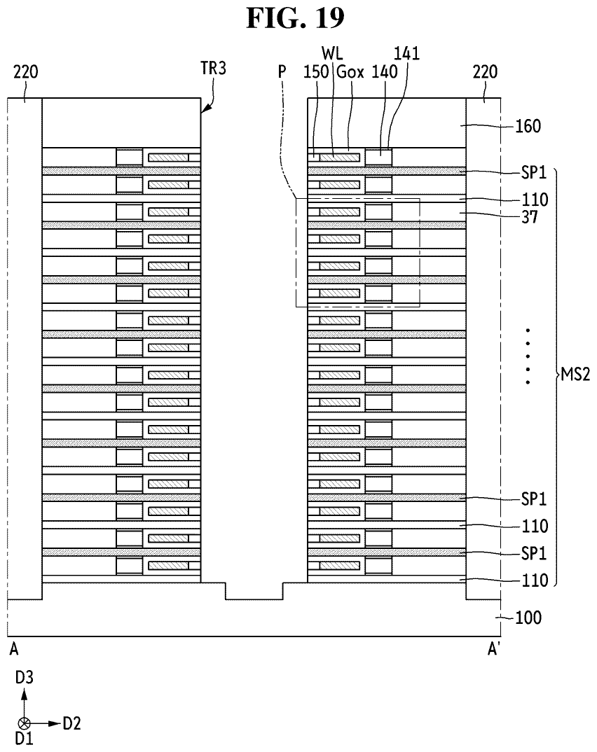

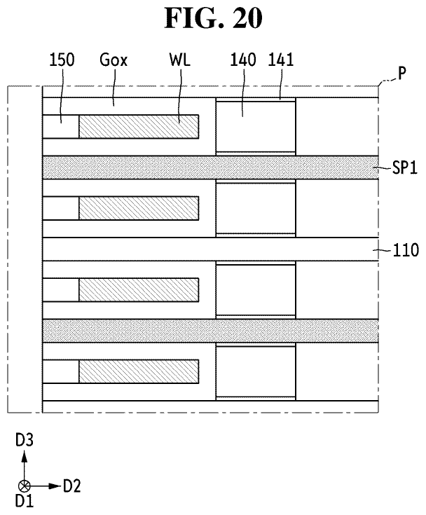

Referring to FIGS. 19 and 20, a third trench TR3 may be formed by etching portions of the first buried insulating pattern 210 and the second mold structure MS2. The width of the third trenches TR3 may be greater than that of the first buried insulating pattern 210.

Thereafter, portions of the second sacrificial patterns 35 exposed by the third trenches TR3 may be removed. The second sacrificial patterns 35 may be removed through an isotropic etching process. The second sacrificial patterns 35 may be selectively removed without removing the interlayer insulating films 110 and the first semiconductor patterns SP1.

For example, if the second sacrificial patterns 35 are silicon nitride films and the interlayer insulating films 110 are silicon oxide films, an etching solution containing phosphoric acid may be used to etch the second sacrificial patterns 35. Portions of the second sacrificial patterns 35 may be removed to form third sacrificial patterns 37.

Spacer insulating films 140 and inner insulating films 141 may be formed in the spaces where the second sacrificial patterns 35 have been removed. The spacer insulating films 140 and the inner insulating films 141 may fill portions of the spaces from which the second sacrificial patterns 35 have been removed. Thereafter, gate insulating films Gox, wordlines WL, and capping insulating films 150 may be formed in the spaces that remain unfilled by the spacer insulating films 140 and the inner insulating films 141.

The gate insulating films Gox may be formed along the profile of the spaces filled by the spacer insulating films 140 and the inner insulating films 141. The wordlines WL and capping insulating films 150 may be sequentially formed on the gate insulating films Gox.

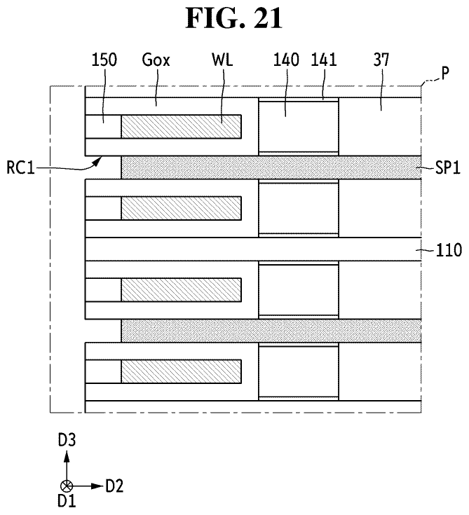

Referring to FIG. 21, first recesses RC1 may be formed by etching portions of the first semiconductor patterns SP1. The first semiconductor patterns SP1 may be isotropically etched using an etching solution that has an etch selectivity with respect to the gate insulating films Gox and the capping insulating films 150. Accordingly, only the first semiconductor patterns SP1 may be selectively removed. The depth of the first recesses RC1 may be substantially equal to the thickness of the capping insulating films 150 in the second direction D2, but the present disclosure is not limited thereto.

If the etching solution contains fluorine (F), chlorine (Cl), or bromine (Br), F, Cl, or Br may be detected on the surfaces of the exposed first semiconductor patterns SP1. Additionally, oxygen (O) may also be detected on the surfaces of the exposed first semiconductor patterns SP1.

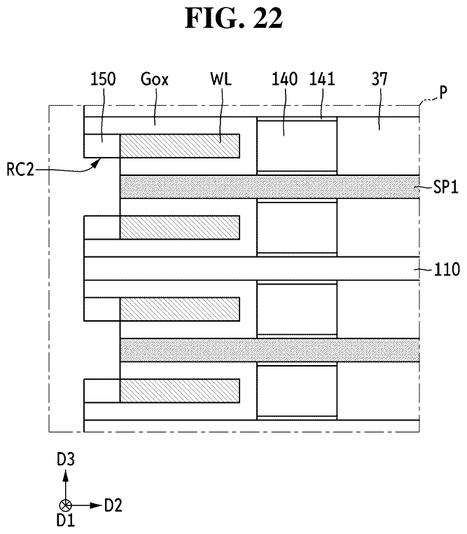

Referring to FIG. 22, second recesses RC2 may be formed by removing portions of the gate insulating films Gox. The second recesses RC2 may expose the surfaces of the capping insulating films 150. The second recesses RC2 do not expose the wordlines WL.

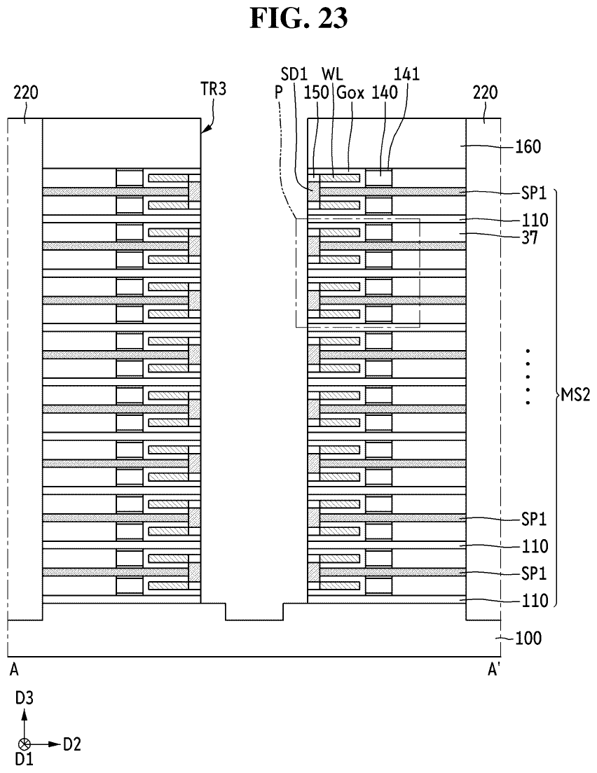

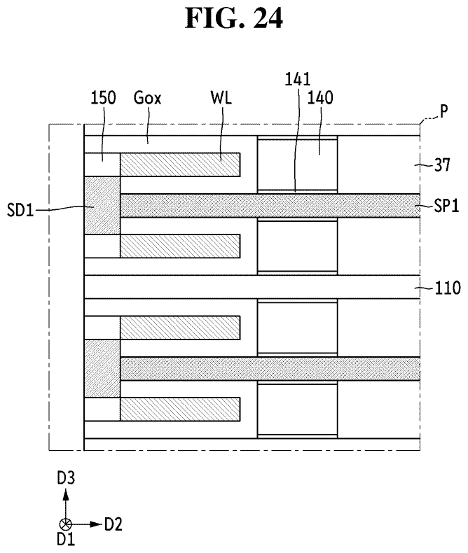

Referring to FIGS. 23 and 24, first source/drain regions SD1 may be formed. The first source/drain regions SD1 may be formed using a selective epitaxial growth (SEG) process. The first source/drain regions SD1 may fill the interior of the second recesses RC2.

In some example embodiments, the surfaces of the first semiconductor patterns SP1 may be exposed by first forming the first recesses RC1 and the second recesses RC2. Thus, oxygen (O) may be present at the interfaces between the surfaces of the exposed first semiconductor patterns SP1 and the first source/drain regions SD1. Additionally, if an etching solution containing F, Cl, or Br is used during the formation of the first recesses RC1, F, Cl, or Br may be present at the interfaces between the surfaces of the semiconductor patterns SP and the first source/drain regions SD1.

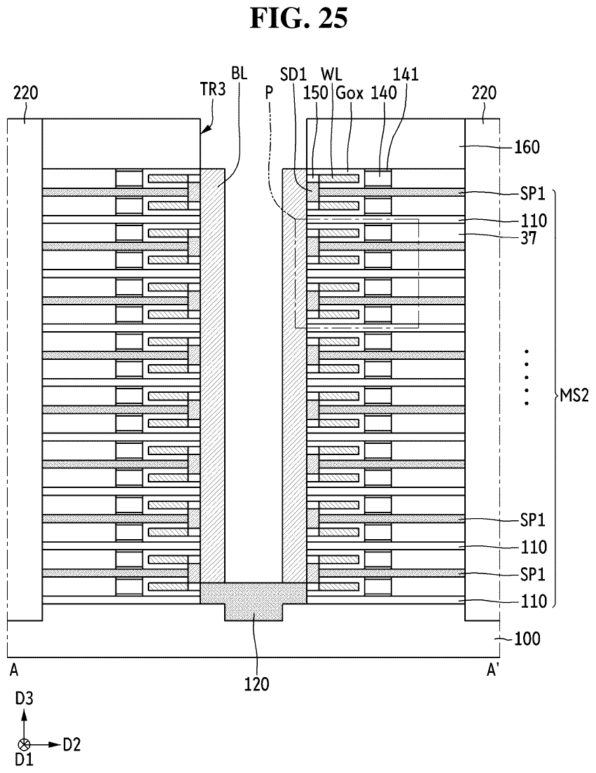

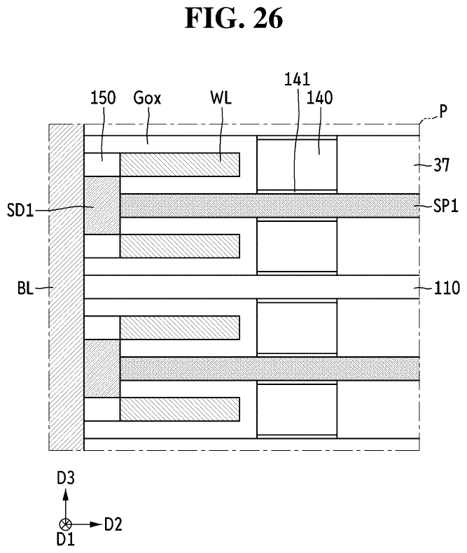

Referring to FIGS. 25 and 26, bitlines BL covering the first source/drain regions SD1, the capping insulating films 150, and the interlayer insulating films 110 may be formed.

Forming the bitlines BL may involve forming a conductive film to fill the third trench TR3 and removing portions of the conductive film. The bitlines BL may cover the first source/drain regions SD1.

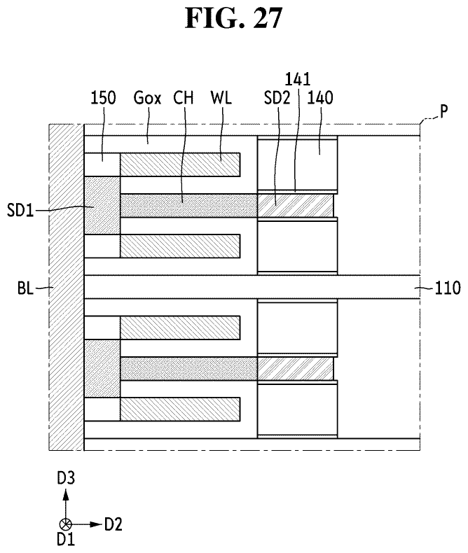

Referring to FIG. 27, second source/drain regions SD2 may be formed by doping portions of the first semiconductor patterns SP1, and the third sacrificial patterns 37 may be removed.

The third sacrificial patterns 37 may be removed, and portions of the second source/drain regions SD2 may also be removed. The inner insulating films 141 may protrude in the second direction D2 beyond the second source/drain regions SD2.

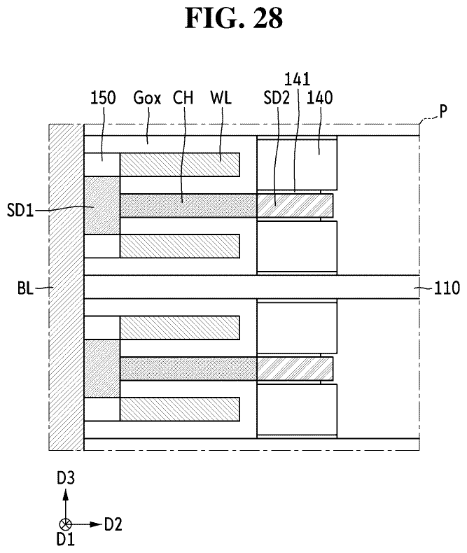

Referring to FIG. 28, portions of the inner insulating films 141 formed on the second source/drain regions SD2 may be removed using a recess process.

By removing portions of the inner insulating films 141, empty spaces may be formed between the second source/drain regions SD2 and the spacer insulating films 140. The second source/drain regions SD2 may protrude in the second direction D2 beyond the inner insulating films 141.

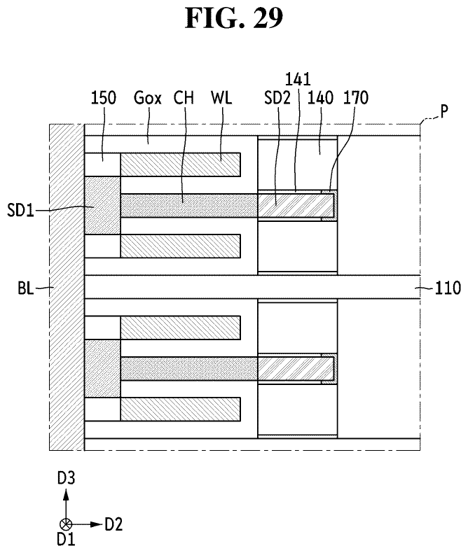

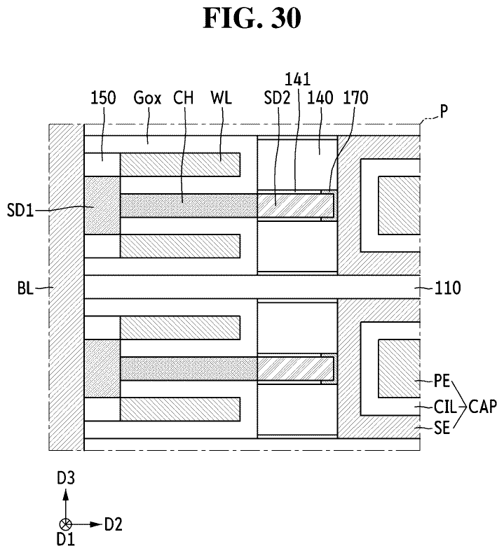

Referring to FIGS. 29 and 30, capping films 170 may be formed on the inner insulating films 141 and the second source/drain regions SD2. Thereafter, data storage elements CAP may be formed on the capping films 170. The capping films 170 may connect the second source/drain regions SD2 and the data storage elements CAP.

Although some example embodiments of the present disclosure have been described with reference to the accompanying drawings, the present disclosure is not limited to the above example embodiments but may be implemented in various different forms. A person skilled in the art may appreciate that the present disclosure may be practiced in other concrete forms without changing the technical spirit or essential characteristics of the present disclosure. Therefore, it should be appreciated that the example embodiments as described above is not restrictive but illustrative in all respects.

What is claimed is:

1. A semiconductor memory device comprising:
a substrate;
a plurality of wordlines stacked in a first direction on the substrate;
channel regions between corresponding pairs of adjacent wordlines from among the plurality of wordlines, respectively, in the first direction, the channel regions extending in a second direction;
first source/drain regions on first sides of the channel regions, respectively;
second source/drain regions on second sides of the channel regions, respectively;
bitlines extending in the first direction on the substrate, each of the bitlines connected to a group of the first source/drain regions;
data storage elements on the substrate and connected to corresponding ones of the second source/drain regions, respectively; and
capping films between the second source/drain regions and corresponding ones of the data storage elements, respectively, the capping film including insertion holes, respectively,
wherein first portions of the second source/drain regions are inserted into corresponding ones of the insertion holes of the capping films, respectively.

2. The semiconductor memory device of claim 1, wherein the first portions of the second source/drain regions are not exposed by the corresponding ones of the capping films, respectively.

3. The semiconductor memory device of claim 1, further comprising:
inner insulating films on corresponding ones of the capping films, respectively, in the second direction, the inner insulating films surrounding second portions of corresponding ones of the second source/drain regions, respectively.

4. The semiconductor memory device of claim 3, wherein an upper surface of each of the capping films and an upper surface of a corresponding one of the inner insulating films are on a same plane.

5. The semiconductor memory device of claim 3, wherein a lower surface of each of the capping films and a lower surface of a corresponding one of the inner insulating films are on a same plane.

6. The semiconductor memory device of claim 3, wherein
the first portions of the second source/drain regions include first surfaces, upper surfaces, lower surfaces, first side surfaces and second side surfaces, the first surfaces in contact with corresponding ones of the capping films, respectively, in the second direction, each of the upper surfaces and a corresponding one of the lower surfaces being opposite to each other in the first direction, each of the first side surfaces and a corresponding one of the second side surfaces being opposite to each other in a third direction, and
the capping films are in contact with the first surfaces, the upper surfaces, the lower surfaces, the first side surfaces, and the second side surfaces of the first portions.

7. The semiconductor memory device of claim 3, wherein
the capping films include vertical portions in contact with the data storage elements and protruding portions extending from the vertical portions in the second direction,
the first portions of the second source/drain regions include upper surfaces, lower surfaces, first side surfaces and second side surfaces, each of the upper surfaces and a corresponding one of the lower surfaces being opposite to each other in the first direction, each of the first side surfaces and a corresponding one of the second side surfaces being opposite to each other in a third direction, and
the protruding portions of the capping films are on the upper surfaces, the lower surfaces, the first side surfaces, and the second side surfaces of the first portions of the second source/drain regions.

8. The semiconductor memory device of claim 1, wherein
the capping films include outer side surfaces in contact with the data storage elements and inner side surfaces in contact with the second source/drain regions, and
the outer side surfaces of the capping films are convex toward the data storage elements.

9. The semiconductor memory device of claim 1, wherein
the capping films include outer side surfaces in contact with the data storage elements and inner side surfaces in contact with the second source/drain regions, and
the outer side surfaces of the capping films are concave toward the data storage elements.

10. The semiconductor memory device of claim 1, wherein
the second source/drain regions include silicon, and
the capping films include a metal silicide.

11. The semiconductor memory device of claim 1, wherein
the second source/drain regions include an oxide semiconductor material, and
the capping films include at least one of indium oxide, indium tin oxide, ruthenium oxide, molybdenum oxide, titanium nitride, molybdenum, or ruthenium.

12. The semiconductor memory device of claim 1, wherein
the second source/drain regions include a two-dimensional material, and
the capping films include at least one of antimony, antimony telluride, palladium nickel, nickel/gold, titanium, chromium, palladium, gold, platinum, silver, copper, nickel, or cobalt.

13. The semiconductor memory device of claim 1, wherein a first width of the capping films in the first direction is smaller than a second width of the data storage elements in the first direction.

14. A semiconductor memory device comprising:
a substrate;
a plurality of wordlines stacked in a first direction on the substrate;
semiconductor patterns between corresponding pairs of adjacent wordlines from among the plurality of wordlines in the first direction, the semiconductor patterns extending in a second direction, the semiconductor patterns including first terminals and second terminals, each of the first terminals and a corresponding one of the second terminals spaced apart in the second direction;
bitlines extending in the first direction on the substrate, each of the bitlines connected to a group of the first terminals of the semiconductor patterns;
capping films connected to corresponding ones of the second terminals of the semiconductor patterns, respectively; and
data storage elements connected to corresponding ones of the capping films, respectively,
wherein
the capping films include vertical portions, protruding portions, and insertion holes, each of the insertion holes defined by a corresponding one of the vertical portions and a corresponding one of the protruding portions, the vertical portions in contact with corresponding ones of the data storage elements, respectively, the protruding portions extending from corresponding ones of the vertical portions, respectively, in the second direction, and
first portions of the semiconductor patterns each are inserted into a corresponding one of the insertion holes at a corresponding one of the second terminals.

15. The semiconductor memory device of claim 14, further comprising:
inner insulating films on corresponding ones of the capping films, respectively, in the second direction, the inner insulating films surrounding second portions of corresponding ones of the semiconductor patterns, respectively,
wherein an upper surface of each of the inner insulating films and an upper surface of a corresponding one of the capping films are on a same plane.

16. The semiconductor memory device of claim 15, wherein
the first portions of the semiconductor patterns includes first surfaces in contact with corresponding ones of the capping films, respectively, in the second direction, upper surfaces, lower surfaces, first side surfaces and second side surfaces, each of the upper surfaces and a corresponding one of the lower surfaces being opposite to each other in the first direction, each of the first side surfaces and a corresponding one of the second side surfaces being opposite to each other in a third direction, and
the capping films are in contact with the first surfaces, the upper surfaces, the lower surfaces, the first side surfaces, and the second side surfaces of the first portions.

17. The semiconductor memory device of claim 14, wherein a width of each of the vertical portions in the first direction is smaller than a width of a corresponding one of the data storage elements in the first direction.

18. The semiconductor memory device of claim 14, wherein the capping films include a metal silicide.

19. A semiconductor memory device comprising:
a substrate;
a plurality of wordlines stacked in a first direction on the substrate;
channel regions between corresponding pairs of adjacent wordlines from among the plurality of wordlines, respectively, in the first direction, the channel regions extending in a second direction;
first source/drain regions on first sides of the channel regions, respectively;
second source/drain regions on second sides of the channel regions, respectively;
bitlines extending in the first direction on the substrate, each of the bitlines connected to a group of the first source/drain regions;
data storage elements on the substrate and connected to corresponding ones of the second source/drain regions, respectively;
inner insulating films on corresponding ones of the second source/drain regions, respectively; and
capping films between the second source/drain regions and corresponding ones of the data storage elements, respectively, the capping films including vertical portions in contact with corresponding ones of the data storage elements, respectively, and protruding portions extending from corresponding ones of the vertical portions, respectively, in the second direction, the protruding portions being in contact with corresponding ones of the inner insulating films, respectively,
wherein
the second source/drain regions include first portions covered by the capping films and second portions covered by the inner insulating films,
the first portions include first surfaces, upper surfaces, lower surfaces, first side surfaces and second side surfaces, the first surfaces being in contact with corresponding ones of the vertical portions, respectively, each of the upper surfaces and a corresponding one of the lower surfaces being in contact with a corresponding one of the protruding portions, each of the upper surfaces and a corresponding one of the lower surfaces being opposite to each other in the first direction, each of the first side surfaces and a corresponding one of the second side surfaces being in contact with a corresponding one of the protruding portions, each of the first side surfaces and a corresponding one of the second side surfaces being opposite to each other in a third direction,
the capping films are in contact with the first surfaces, the upper surfaces, the lower surfaces, the first side surfaces, and the second side surfaces of the first portions, and
each of upper surfaces of the inner insulating films and a corresponding one of upper surfaces of the capping films are on a same plane.

20. The semiconductor memory device of claim 19, wherein
the capping films include outer side surfaces in contact with the data storage elements and inner side surfaces in contact with the second source/drain regions, and
the outer side surfaces of the capping films are convex toward corresponding ones of the data storage elements, respectively.
